(19) United States
(12) Patent Application Publication
(10) Pub. No.: US 2011/0166026 A1
(43) Pub. Date: Jul. 7, 2011

(54) METHOD OF FABRICATIING OXIDE SUPERCONDUCTING THIN FILM

(76) Inventors: Genki Honda, Osaka (JP); Takahiro Taneda, Osaka (JP); Takeshi Kato, Osaka (JP)

(21) Appl. No.: 13/059,598

(22) PCT Filed: Feb. 18, 2009
(86) PCT No.: PCT/JP2009/052769

§ 371 Date: Feb. 17, 2011

(30) Foreign Application Priority Data
Aug. 20, 2008 (JP) 2008-212082

(51) Int. Cl. H01L 39/24; B05D 3/02; B05D 5/12

(52) U.S. Cl. 505/434; 427/62

(57) ABSTRACT

The present invention is a method of fabricating an oxide superconducting thin film for use in fabrication of a superconducting wire by a coating-pyrolysis process using a fluorine-free metal organic compound as a raw material. An intermediate heat treatment of decomposing a carbonate contained in a thin film to be subjected to a sintering heat treatment for a crystallizing heat treatment is conducted before the sintering heat treatment. The intermediate heat treatment is conducted in an atmosphere having a carbon dioxide concentration lower than or equal to 10 ppm. The metal organic compound is a metal organic compound containing a β-diketone complex.

### TECHNICAL FIELD

The present invention relates to a method of fabricating an oxide superconducting thin film, and specifically relates to a method of fabricating an oxide superconducting thin film having a high critical current value for use in fabrication of a superconducting wire.

### BACKGROUND ART

To permit more widespread use of a superconducting wire in which an oxide superconducting thin film is used, studies are being made on fabrication of an oxide superconducting thin film with a higher critical current density Jc and a higher critical current value Ic.

One of methods of fabricating oxide superconductors is a method called coating-pyrolysis process (Metal Organic Deposition, abbreviated to MOD process). This process involves coating a substrate with a solution of a metal organic compound, and then calcining the metal organic compound at, for example, around 500° C. for pyrolysis, and heat treating (sintering) the obtained pyrolysate (MOD calcined film) at an even higher temperature (for example, around 800° C.) for achieving crystallization, so that a superconductor is obtained. The process is characterized by a simpler manufacturing facility and easier accommodation to a large area and a complicated shape than in a gas phase process fabricated mainly under vacuum (vapor deposition, sputtering, pulsed-laser vapor deposition, etc).

However, in crystallization, a superconducting current does not flow smoothly unless the superconductor has aligned crystal orientation, which reduces a critical current density Jc (hereinafter also briefly referred to as “Jc”) and a critical current value Ic (Ic=Jc×film thickness x width) (hereinafter also briefly referred to as “Ic”). Therefore, crystals need to be epitaxially grown to take over the orientation of an orientation substrate, and the crystal growth needs to progress from the substrate toward the film surface.

The above-mentioned coating-pyrolysis process includes a TFA-MOD process (Metal Organic Deposition using TriFluoroAcetates) in which a fluorine-containing organic acid salt is used as a raw material and a fluorine-free MOD process in which a fluorine-free metal organic compound is used.

By means of the TFA-MOD process, an oxide superconducting thin film having a favorable in-plane orientation can be obtained, and Japanese Patent Laying-Open No. 2007-165153 (hereinafter, Patent Document 1) proposes a method of fabricating a thick film superconductor by the TFA-MOD process. However, by the TFA-MOD process, a fluoride, specifically, BaF₂, for example, is produced at the time of calcination, and this BaF₂ is pyrolyzed at the time of sintering to generate a dangerous hydrogen fluoride gas. Therefore, an apparatus or facility for processing the hydrogen fluoride gas is necessary (“Toshiya Kumagai et al., “Fabrication of Superconducting Film By Dipping-Pyrolysis Process”, The journal of The Surface Finishing Society of Japan, 1991, Vol. 42, No. 5, p. 500 to 507”(hereinafter, Non-Patent Document 1); ““Fabrication of Superconducting Thin Film Using Laser Beam Irradiation in Combination”, AIST TODAY, National Institute of Advanced Industrial Science and Technology, 2006, Vol. 6 to 11, p. 12 to 15” (hereinafter, Non-Patent Document 2)).

In contrast, the fluorine-free MOD process is advantageous in that a dangerous gas such as hydrogen fluoride is not produced, which is environmentally friendly and requires no processing facility. However, in the fluorine-free MOD process, a carbonate of an alkaline earth metal, specifically, BaCO₃, for example, is produced at the time of calcination, and contained in a calcined film. If this BaCO₃ is not pyrolized in the sintering step, crystallization of superconductor does not take place. In the conventional heat treatment process, BaCO₃ is pyrolized in the sintering step, however, crystal orientation may be disordered. This is believed to be attributed to creation of voids in the film due to a CO₂ gas produced in pyrolysis, which inhibits crystal growth from the substrate, and attributed to pyrolysis of BaCO₃ everywhere in the film, which causes crystals to grow therefrom. Therefore, when the film is set at a certain thickness, Jc is abruptly reduced to abruptly reduce Ic, or with a film thickness by which high Jc is easily obtained, the characteristic of easy obtaining of high Jc cannot be achieved with good reproducibility.

An exemplary method of fabricating an oxide superconducting thin film by the fluorine-free MOD process is described in Non-Patent Document 1. Non-Patent Document 2 discloses a method of uniformly pyrolizing a raw material contained in a coating film by excimer-laser irradiation to bring about uniform crystal growth.

### PRIOR ART DOCUMENTS

### Patent Documents

Patent Document 1: Japanese Patent Laying-Open No. 2007-165153
Non-Patent Document 1: Toshiya Kumagai et al., “Fabrication of Superconducting Film By Dipping-Pyrolysis Process”, The journal of The Surface Finishing Society of Japan, 1991, Vol. 42, No. 5, p. 500 to 507
Non-Patent Document 2: “Fabrication of Superconducting Thin Film Using Laser Beam Irradiation in Combination”, AIST TODAY, National Institute of Advanced Industrial Science and Technology, 2006, Vol. 6 to 11, p. 12 to 15

### SUMMARY OF THE INVENTION

### Problems to be Solved by the Invention

However, the method disclosed in Non-Patent Document 1 is disadvantageous in that, due to insufficient ejection of CO₂ produced in the heat treatment step, the film cannot be increased in thickness without fluorine with high Jc, nor high Ic can be obtained.

The method disclosed in Non-Patent Document 2 is also disadvantageous in that an expensive laser apparatus is required, leading to increased costs. In addition, Jc of the order of 6 MA/cm² is obtained by this method, however, the film thickness is as thin as 0.1 μm, which cannot achieve high Ic.

Therefore, the present invention has an object to provide a method of fabricating an oxide superconducting thin film, the method fabricating an oxide superconducting thin film used in fabrication of a superconducting wire by a coating-pyrolysis process using a fluorine-free metal organic compound, wherein BaCO₃ contained in a calcined film is efficiently pyrolized to enable crystal growth to progress from a substrate, as a result of which the film can be increased in thickness with high Jc (for example, higher than or equal to 1 MA/cm²), and a high Ic value can be obtained with good reproducibility.

### Means for Solving the Problems

As a result of intense studies in light of the above-mentioned object, the inventors of the present invention have found out that conducting an intermediate heat treatment of pyrolizing a carbonate in advance before a heat treatment of sintering (hereinafter referred to as “sintering heat treatment”) for a crystallizing heat treatment can achieve the above-mentioned object, thereby completing the present invention.

The method of fabricating an oxide film superconducting thin film in accordance with the present invention is a method of fabricating an oxide superconducting thin film for use in fabrication of a superconducting wire by a coating-pyrolysis process using a fluorine-free metal organic compound as a raw material. The method includes the steps of conducting the intermediate heat treatment of pyrolizing the carbonate contained in a thin film yet to be subjected to the sintering heat treatment, and conducting the sintering heat treatment for the crystallizing heat treatment on the thin film having been subjected to the intermediate heat treatment.

In the method of fabricating an oxide film superconducting thin film in accordance with the present invention, the intermediate heat treatment of pyrolizing the carbonate contained in the thin film to be subjected to the sintering heat treatment for the crystallizing heat treatment is conducted before the sintering heat treatment to remove a factor that inhibits crystal growth from a substrate. Therefore, in the sintering heat treatment, an oxide superconducting thin film with improved orientation can be obtained as a result of crystal growth progressed from the substrate. That is, a thick MOD sintered film having high Jc (for example, higher than or equal to 1 MA/cm²) can be fabricated, so that an oxide superconducting thin film having a high Ic value can be obtained with good reproducibility. Further, the obtained oxide superconducting thin film can be used suitably for fabrication of a superconducting wire.

In the method of fabricating an oxide film superconducting thin film in accordance with the present invention, the intermediate heat treatment is preferably conducted in an atmosphere having a carbon dioxide concentration lower than or equal to 10 ppm.

The inventors of the present invention have found out that the carbon dioxide concentration in an atmosphere significantly influences ease of carbonate pyrolysis in the intermediate heat treatment. Then, studies on the relationship between the carbon dioxide concentration and carbonate pyrolysis have revealed that, at a carbon dioxide concentration lower than or equal to 10 ppm, carbonate pyrolysis progresses more easily, so that a more stable oxide superconducting thin film having high Ic can be obtained.

In the method of fabricating an oxide film superconducting thin film in accordance with the present invention, the metal organic compound is preferably a metal organic compound containing a β-diketone complex. When the metal organic compound is a material containing a β-diketone complex, the intermediate heat treatment exerts greater effects.

In the method of fabricating an oxide film superconducting thin film in accordance with the present invention, the intermediate heat treatment is preferably a heat treatment conducted within a temperature range higher than or equal to 620° C. and lower than or equal to 750° C.

When the temperature in the intermediate heat treatment is higher than or equal to 620° C. and lower than or equal to 750° C., carbonate is pyrolized more reliably.

### Effects of the Invention

According to the present invention, as a result of progress of crystal growth from the substrate, an oxide superconducting thin film with improved orientation and good reproducibility, and having a high Ic value can be obtained.

### BRIEF DESCRIPTION OF THE DRAWINGS

FIG. 1 is a flow chart showing a method of fabricating an oxide film superconducting thin film in an embodiment of the present invention.

FIG. 2 is a diagram showing a relationship between critical current value Ic and film thickness in Examples 1.

FIG. 3 is a diagram showing a relationship between Y123(006) peak intensity and film thickness in Examples 1.

FIG. 4 is a diagram showing a relationship between critical current value Ic and film thickness in Examples 2.

FIG. 5 is a diagram showing a relationship between Ho123(006) peak intensity and film thickness in Examples 2.

FIG. 6 is a diagram showing a dissociation curve of BaCO₃.

FIG. 7 is a diagram illustrating a relationship between pyrolysis of BaCO₃ and temperature.

FIG. 8 is a diagram illustrating a relationship between crystal growth of YBCO and temperature.

FIG. 9 is a diagram illustrating a pattern of an intermediate heat treatment and a sintering heat treatment.

### MODES FOR CARRYING OUT THE INVENTION

Hereinafter, the present invention will be described based on the best embodiment thereof. It is to be noted that the present invention is not limited to the following embodiment. Various modifications can be added to the following embodiment within a scope identical and equivalent to the present invention.

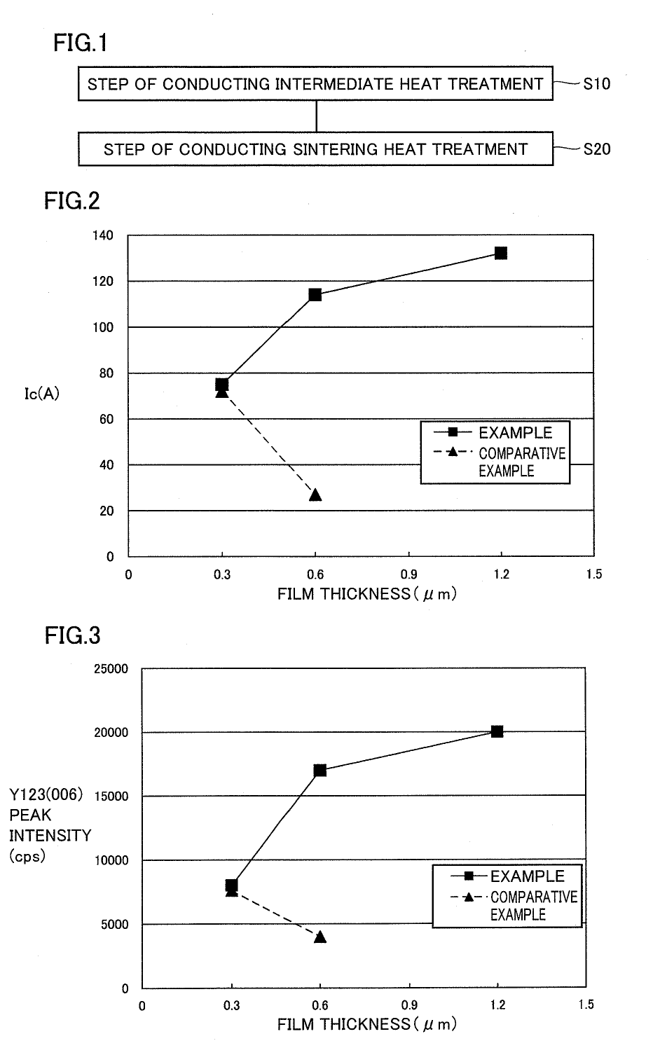

As described above, the present invention is characterized by conducting an intermediate heat treatment of pyrolizing a carbonate contained in a film to be subjected to a sintering heat treatment for a crystallizing heat treatment, using a fluorine-free metal organic compound as a raw material, before the sintering heat treatment. In other words, as shown in FIG. 1, the method of fabricating an oxide superconducting thin film includes the steps of conducting (S10) the intermediate heat treatment of pyrolizing a carbonate contained in a thin film yet to be subjected to the sintering heat treatment, and conducting (S20) the sintering heat treatment for a crystallizing heat treatment on the thin film having been subjected to the intermediate heat treatment.

(As to Raw Material)

As a fluorine-free metal organic compound, metal salts having a carboxyl group (salts of naphthenic acid, salts of octylic acid, salts of neodecanoic acid, salts of isononanoic acid, etc.), amine metal salts having an amino group, amino acid metal salts composed of an amino group and a carboxyl group, nitrates, metal alkoxides, acetylacetonates, and so forth are used. Among these, a β-diketone complex such as acetylacetonate is preferable.

The metal in the above-mentioned metal organic compound can include yttrium (Y), barium (Ba), copper (Cu), praseodymium (Pr), neodymium (Nd), samarium (Sm), europium (Eu), gadolinium (Gd), holmium (Ho), ytterbium (Yb), and so forth.

An organic Ba compound and an organic Cu compound are combined with another metal organic compound, and dissolved in a solvent such that the respective metal elements have a predetermined molar ratio, to thereby prepare an MOD solution in accordance with the present invention, so that an oxide superconducting thin film can be obtained finally. For example, in combination with an organic Y compound, a YBCO thin film is obtained, and in combination with an organic Ho compound, an HoBCO thin film is obtained.

(As to Intermediate Heat Treatment)

The step (S10) of conducting an intermediate heat treatment is a step of subjecting a carbonate produced in a calcining step to a pyrolysis treatment, which needs to be conducted at temperatures lower than a temperature in the sintering process in order to prevent crystallization.

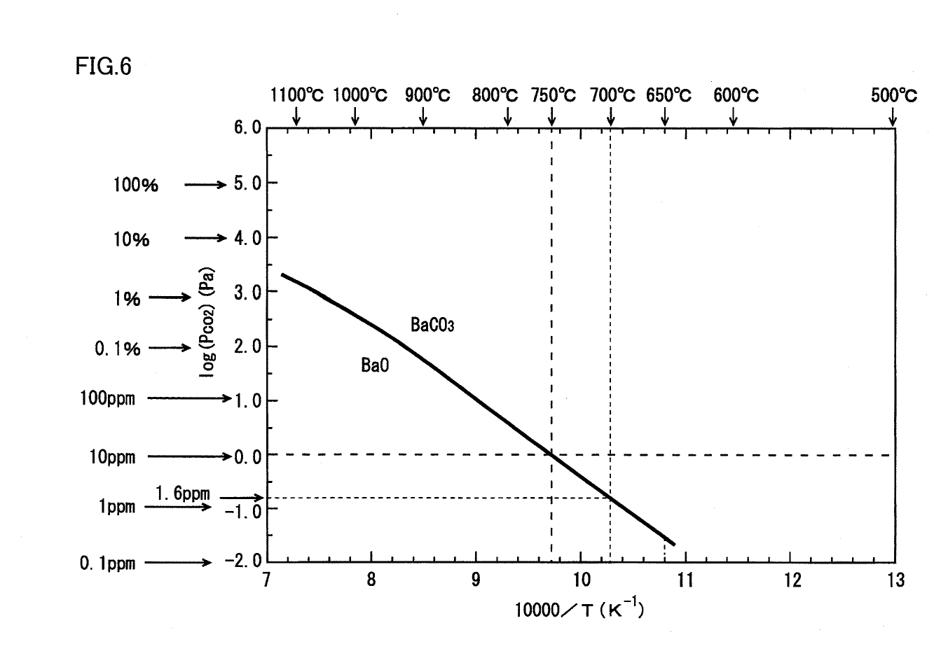

Therefore, the relationship between pyrolysis of carbonate and temperature was previously studied as will be described below. FIG. 6 is a diagram created by extracting a dissociation curve of BaCO₃ related to the present invention from “Dissociation curve of carbonic acid group in alkaline earth salt” shown in page 387 of SCIENCE OF HIGH TEMPERATURE SUPERCONDUCTIVITY edited by Masashi Tachiki and Toshizo Fujita (SHOKABO PUBLISHING CO., LTD., published in 2001). FIG. 6 shows that, for example, at an ambient temperature of 700° C., BaCO₃ is pyrolized in an atmosphere of a CO₂ concentration lower than or equal to 1.6 ppm to be turned into BaO.

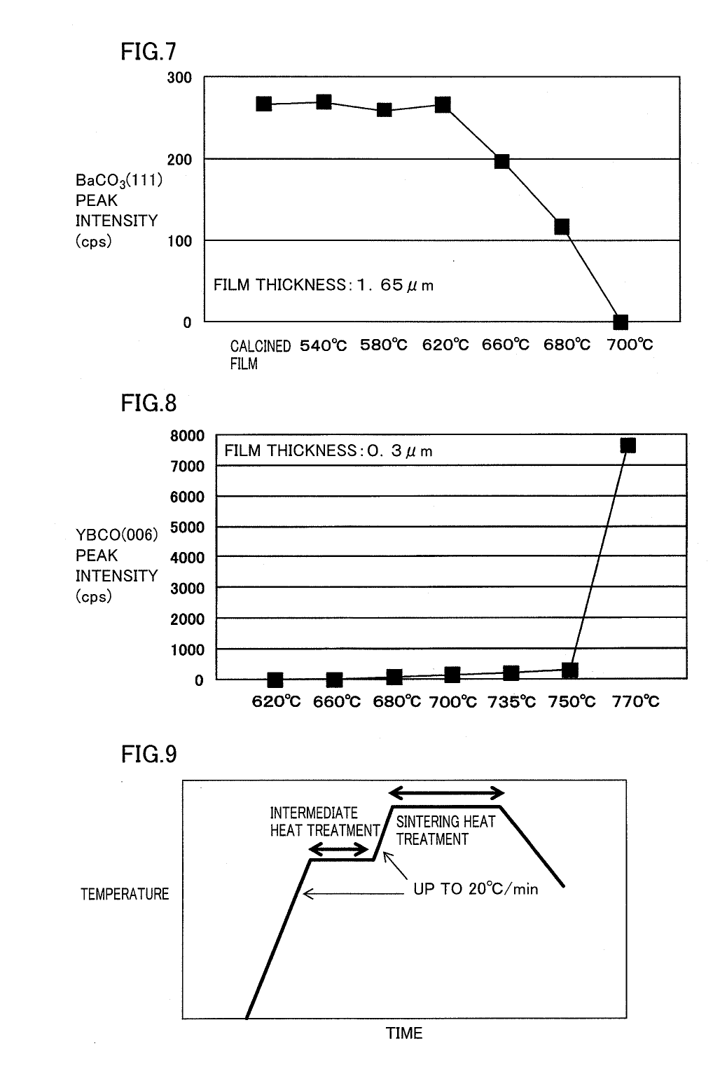

Then, the following experiment was conducted with reference to the foregoing. At first, a specimen a having a BaCO₃ film of 1.65 μm in film thickness was formed on a substrate, and a specimen b having a YBCO film of 0.30 μm in film thickness was formed on the substrate. Then, each of specimens a and b were raised in temperature to the temperatures shown in the horizontal axes of FIGS. 7 and 8, respectively, and maintained for 10 minutes, and thereafter furnace cooled to a room temperature. It is to be noted that either CO₂ concentration at this time was lower than or equal to 1 ppm. Then, the peak intensity by XRD of BaCO₃(111) in specimen a and the peak intensity by XRD of YBCO(006) in specimen b were measured. Test results are shown in FIGS. 7 and 8, respectively.

As shown in FIG. 7, the peak intensity of BaCO₃(111) gradually decreases from about 620° C., and decreases more sharply with temperature rise to reach 0 at 700° C. This shows that pyrolysis of BaCO₃ starts gradually at about 620° C., and the amount of pyrolysis increases with temperature rise, and pyrolysis of all BaCO₃ ends at 700° C.

Also, as shown in FIG. 8, the peak intensity of YBCO(006) abruptly increases above 750° C. This shows that the crystal growth rate of YBCO abruptly increases above 750° C.

With reference to the foregoing, conditions for the intermediate heat treatment were studied. Specifically, the intermediate heat treatment is preferably conducted within a temperature range higher than or equal to a temperature at which pyrolysis of BaCO₃ starts and lower than or equal to a temperature at which crystallization of superconductor does not progress, that is, a temperature range higher than or equal to 620° C. and lower than or equal to 750° C. A processing time longer than or equal to 10 minutes is preferable, although depending on the treatment temperature and the film thickness. For example, in the case where the film thickness is 0.3 μm, and a temperature in the intermediate heat treatment is 680° C., about 10 minutes is favorable, however, these conditions are non-limiting.

As a processing atmosphere, an atmosphere of an argon/oxygen-mixed gas or a nitrogen/oxygen-mixed gas is preferable. At that time, an oxygen concentration is preferably about 100 ppm, and a CO₂ concentration is preferably lower than or equal to 10 ppm from FIG. 6. Under such an atmosphere, pyrolysis of carbonate progresses more easily.

### (As to Sintering Heat Treatment)

The highest temperature at the step (S20) of conducting the sintering heat treatment is preferably lower than or equal to 800° C., but is not particularly limited, and is determined at an appropriate temperature depending on the type of metal, and so forth.

(As to Substrate)

As the substrate in the present invention, crystals constituting the uppermost layer is preferably biaxially oriented. A superconductive layer is formed on the biaxially-oriented substrate, so that crystals with good orientation are grown. The uppermost layer includes, for example, a CeO₂ layer, and the substrate includes, for example, a CeO₂/YSZ/CeO₂/Ni alloy substrate.

Examples and comparative examples will be described below.

### Examples 1 and Comparative Examples 1

The present examples and the comparative examples are examples in which a YBCO thin film indicated by Y123 (an oxide superconducting thin film made of Y—Ba—Cu—O, a molar ratio of Y:Ba:Cu being 1:2:3) was fabricated on the substrate.

A CeO₂/YSZ/CeO₂/Ni alloy substrate was used as the substrate. This substrate was coated with a raw material solution obtained by preparing the respective acetylacetonate complexes of Y, Ba and Cu such that a molar ratio of Y:Ba:Cu was 1:2:3 and dissolving them in a solvent (a mixed solvent of methanol and 1-butanol), and was raised in temperature in atmospheric air to 500° C. at a temperature rise rate of 20° C./min, and maintained for 2 hours, followed by furnace cooling, thereby achieving a calcining heat treatment. At this stage, the film thickness increased by about 0.15 μm per treatment. This coating and calcining step was repeated several times to obtain a prescribed film thickness.

Then, the following intermediate heat treatment and the sintering heat treatment were conducted. These heat treatments were conducted only once per sample. An exemplary heat treatment pattern is shown in FIG. 9.

First, the intermediate heat treatment was conducted by heating at temperatures and was maintained for time periods shown in Examples 1-1, 1-2, and 1-3 in Table 1 in an atmosphere of an argon/oxygen-mixed gas (oxygen concentration: 100 ppm, CO₂ concentration: lower than or equal to 1 ppm).

After the intermediate heat treatment, the sintering heat treatment was conducted by heating at the heat treatment temperatures and for the time periods shown in Table 1 in an atmosphere of an argon/oxygen-mixed gas (oxygen concentration: 100 ppm, CO₂ concentration: lower than or equal to 1 ppm) for crystallization, followed by furnace cooling in an atmosphere of an oxygen concentration of 100%, thereby obtaining Y123 thin films having film thicknesses shown in Examples 1-1, 1-2, and 1-3 in Table 1.

Next, as a comparative example, a Y123 thin film of Comparative Example 1-1 was obtained under identical conditions to those in Example 1-1 except that the intermediate heat treatment was not conducted. A Y123 thin film of Comparative Example 1-2 was also obtained under identical conditions to those in Example 1-2 except that the intermediate heat treatment was not conducted.

Jc and Ic in each of the Y123 thin films obtained in the respective Examples and Comparative Examples were measured at a temperature of 77K in a self magnetic field. The Y123(006) peak intensity by XRD was also measured to confirm situations of c-axis orientation of crystals in the sintered film.

The measurement results are also shown in Table 1. The relationship between Ic and film thickness is shown in FIG. 2, and the relationship between Y123(006) peak intensity and film thickness is shown in FIG. 3.

TABLE 1

| | | | | | Comparative | |
|---|---|---|---|---|---|---|
| | | Examples 1 | | | Examples 1 | |
| | | 1-1 | 1-2 | 1-3 | 1-1 | 1-2 |
| Film Thickness after Sintering (μm) | | 0.3 | 0.6 | 1.2 | 0.3 | 0.6 |
| Intermediate Heat | Temperature (° C.) | 680 | 680 | 680 | None | None |
| Treatment | Time (min) | 10 | 180 | 180 | | |
| Sintering Heat | Temperature (° C.) | 770 | 770 | 770 | 770 | 770 |
| Treatment | Time (min) | 90 | 90 | 90 | 90 | 90 |

| | | | | | |
|---|---|---|---|---|---|
| Critical Current Density Jc (MA/cm²) | 2.5 | 1.9 | 1.1 | 2.4 | 0.5 |
| Critical Current Ic (A) | 75 | 114 | 132 | 72 | 27 |
| Y123(006) Peak Intensity (cps) | 8000 | 17000 | 20000 | 7600 | 4000 |

Table 1 and FIGS. 2 and 3 show the following. More specifically, in the case where the film thickness is 0.3 μm (Example 1-1 and Comparative Example 1-1), Ic in Example 1-1 is 75(A) while Ic in Comparative Example 1-1 is 72(A), so that there is little difference therebetween, which means that the effects of the intermediate heat treatment are hardly exerted in the case where the film thickness is thin. This is presumed because, in the case where the film thickness is thin, BaCO₃ is sufficiently pyrolized at an early stage of heating even when the sintering heat treatment is conducted without conducting the intermediate heat treatment, causing crystallization with less disordered orientation to progress, which resulted in a small difference between the presence and absence of the intermediate heat treatment.

In contrast, in the case where the film thickness is 0.6 μm (Example 1-2 and Comparative Example 1-2), Ic in Example 1-2 is increased to 114(A) as compared to that in Example 1-1 while Ic in Comparative Example 1-2 is reduced to 27(A) as compared to that in Comparative Example 1-1. In the case where the film thickness is 1.2 μm (Example 1-3), Ic is further increased to 132(A) as compared to that in Example 1-2.

This is presumed because, in the case where the film thickness is thick, BaCO₃ is sufficiently pyrolized by conducting the intermediate heat treatment in advance and then the sintering heat treatment, causing crystal growth from the substrate to progress, which led to increased Ic.

This can also be readily appreciated from FIG. 3 illustrating the relationship between Y123(006) peak intensity and film thickness in Examples and Comparative Examples in Table 1. More specifically, the peak intensity is an index indicating the c-axis orientation of crystals, and increases in proportion to the amount of crystals oriented along the c-axis. As shown in FIG. 3, the peak intensity in Example 1-2 is stronger than that in Comparative Example 1-2. These films have the same film thickness, and the stronger peak intensity means that the c-axis orientation has been improved. Further, in the present embodiment, the peak intensity increases as the film thickness increases. That is, the peak intensity in Example 1-2 is higher than that in Example 1-1, and the peak intensity in Example 1-3 is even higher than that in Example 1-2, which clearly shows that, even with the film thickness increased, crystal growth from the substrate progresses, and the amount of crystals oriented along the c-axis increases.

In contrast, it is presumed that pyrolysis of BaCO₃ is insufficient when the sintering heat treatment is conducted without conducting the intermediate heat treatment, causing crystallization with disordered orientation to progress, which led to reduction in Ic.

### Examples 2 and Comparative Examples 2

The present Examples and Comparative Examples are examples in which a HoBCO thin film indicated by Ho 123 (an oxide superconducting thin film made of Ho—Ba—Cu—O, a molar ratio of Ho:Ba:Cu being 1:2:3) was fabricated on the substrate.

Except that Y in Examples 1 and Comparative Examples 1 was replaced by Ho, and conditions of the intermediate heat treatment and the sintering heat treatment were replaced by those shown in Table 2, Ho 123 thin films having film thicknesses shown in Examples 2-1 to 2-3 and Comparative Examples 2-1 and 2-2 in Table 2 were obtained similarly to Examples 1 and Comparative Examples 1, and were subjected to measurements similar to Examples 1.

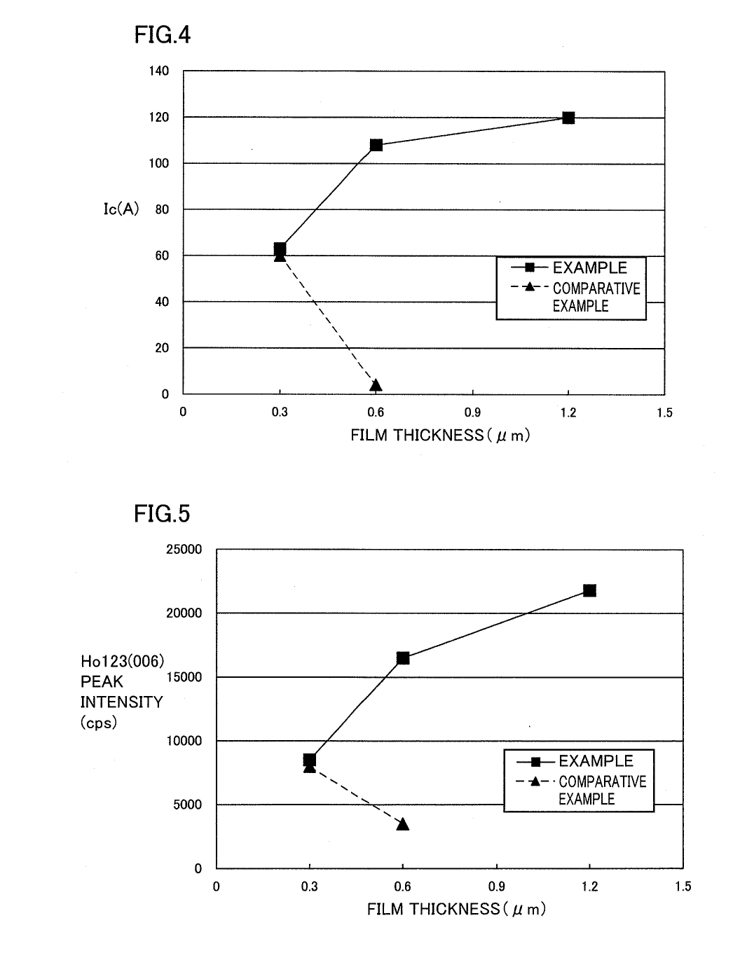

The measurement results are also shown in Table 2. The relationship between Ic and film thickness is shown in FIG. 4, and the relationship between Ho123(006) peak intensity and film thickness is shown in FIG. 5.

TABLE 2

| | | | | | Comparative | |
|---|---|---|---|---|---|---|
| | | Examples 2 | | | Examples 2 | |
| | | 2-1 | 2-2 | 2-3 | 2-1 | 2-2 |
| Film Thickness after Sintering (μm) | | 0.3 | 0.6 | 1.2 | 0.3 | 0.6 |
| Intermediate Heat | Temperature (° C.) | 680 | 680 | 680 | None | None |
| Treatment | Time (min) | 10 | 180 | 180 | | |
| Sintering Heat | Temperature (° C.) | 780 | 780 | 780 | 780 | 780 |
| Treatment | Time (min) | 90 | 90 | 90 | 90 | 90 |

| | | | | | |
|---|---|---|---|---|---|
| Critical Current Density Jc (MA/cm²) | 2.1 | 1.8 | 1.0 | 2.0 | 0.1 |
| Critical Current Ic (A) | 63 | 108 | 120 | 60 | 4 |
| Ho123 (006) Peak Intensity (cps) | 8500 | 16500 | 21800 | 8000 | 3500 |

As shown in Table 2 and FIGS. 4 and 5, tendencies similar to those in Examples 1 could also be confirmed in the present examples, which shows effects exerted by conducing the intermediate heat treatment in the HoBCO thin films as well.

More specifically, in the case where the film thickness is 0.3 μm (Example 2-1 and Comparative Example 2-1), Ic in Example 2-1 is 63(A) while Ic in Comparative Example 2-1 is 60(A), so that there is little difference in Ic similarly to Examples 1, which means that the effects of the intermediate heat treatment are hardly exerted in the case where the film thickness is thin. In contrast, in the case where the film thickness is 0.6 μm (Example 2-2 and Comparative Example 2-2), Ic in Example 2-2 is increased to 108(A) as compared to that in Example 2-1 while Ic in Comparative Example 2-2 is reduced to 4(A) as compared to that in Comparative Example 2-1. In the case where the film thickness is 1.2 μm (Example 2-3), Ic is further increased to 120(A) as compared to that in Example 2-2.

As described above, in the present invention, conducting the intermediate heat treatment in advance before the sintering heat treatment can cause crystal growth from the substrate to progress, leading to improved crystal orientation, as a result of which a high Ic value can be obtained with good reproducibility even in the case of a thick film.

1. A method of fabricating an oxide superconducting thin film for use in fabrication of a superconducting wire by a coating-pyrolysis process using a fluorine-free metal organic compound as a raw material, comprising the steps of:
conducting an intermediate heat treatment of pyrolizing a carbonate contained in a thin film yet to be subjected to a sintering heat treatment; and
conducting said sintering heat treatment for a crystallizing heat treatment on said thin film having been subjected to said intermediate heat treatment, wherein
said intermediate heat treatment is conducted in an atmosphere having a carbon dioxide concentration lower than or equal to 10 ppm, and
said intermediate heat treatment is a heat treatment conducted within a temperature range higher than or equal to 620° C. and lower than or equal to 750° C.

2. (canceled)

3. The method of fabricating an oxide superconducting thin film in accordance with claim 1, characterized in that said metal organic compound is a metal organic compound containing a β-diketone complex.

4. (canceled)

5. The method of fabricating an oxide superconducting thin film in accordance with claim 1, characterized in that a processing time of said intermediate heat treatment is longer than or equal to 10 minutes.

6. The method of fabricating an oxide superconducting thin film in accordance with claim 1, characterized in that said thin film has a film thickness more than or equal to 0.3 μm.

7. The method of fabricating an oxide superconducting thin film in accordance with claim 1, characterized in that said thin film has a film thickness more than or equal to 0.6 μm.
